(19) United States
(12) Patent Application Publication
(10) Pub. No.: US 2013/0044444 A1
(43) Pub. Date: Feb. 21, 2013

(54) SYSTEM ASSEMBLY AND DESIGN OF PHOTOELECTRIC CONTROLLER DEVICE

(71) Applicants: Jason CREIGHTON, Twinsburg, OH (US); Deeder AURONGZEB, Mayfield Heights, OH (US); Tony ABOUMRAD, Parma, OH (US); Michael SELECKY, Cleveland, OH (US)

(72) Inventors: Jason CREIGHTON, Twinsburg, OH (US); Deeder AURONGZEB, Mayfield Heights, OH (US); Tony ABOUMRAD, Parma, OH (US); Michael SELECKY, Cleveland, OH (US)

(73) Assignee: GENERAL ELECTRIC COMPANY, Schenectady, NY (US)

(21) Appl. No.: 13/212,712

(22) Filed: Aug. 18, 2011

(51) Int. Cl. H05K 7/00

(52) U.S. Cl. 361/752

(57) ABSTRACT

A photoelectric controller device includes a housing. At least two printed circuit boards can be secured in an interior of the housing. The printed circuit boards include a photosensor and communication circuitry. Electrically conductive, main terminals are secured in electrical contact with one of the printed circuit boards. A communication terminal is also secured in electrical contact with the communication circuitry on one of the printed circuit boards. Also featured is a design of a base plate of the photoelectric controller device that secures at least one circuit board and a design of a window for the photosensor. The controller may include at least one printed circuit board comprising a sensor selected from the group consisting of the photosensor, an infrared sensor or a visible detector, and combinations thereof.

### FIELD OF THE INVENTION

This disclosure pertains to a photoelectric controller device and, in particular, to features enabling the device to resist UV degradation, dust and a high pressure water spray and, to the assembly of a PCB board and connectors.

### BACKGROUND OF THE INVENTION

Lighting fixtures can be automatically switched on at dusk and off at dawn using twist-lock photoelectric controllers. The lighting fixtures may be used to light roads, parking lots and other areas outdoors. The photoelectric controller senses the intensity of the ambient light and switches the lighting fixtures on and off as appropriate. The photoelectric controllers are typically oriented so that the photosensor faces North, away from direct sunlight in the Northern hemisphere (and in a southerly direction in the Southern hemisphere). It is also desired to be able to easily adjust the receptacle that receives the photoelectric controller to achieve the desired orientation.

Lighting fixtures for street lights typically include an electrical receptacle that receives the photoelectric controller that is mounted to a housing on the top of the lighting fixture. The electrical receptacle is wired to the power supply of the lighting fixture. The photoelectric controller has three main terminals that are inserted into the electrical receptacle and twisted to lock the photoelectric controller to the receptacle.

The orientation of the photoelectric controller in the Northern direction is accomplished by the use of a metal snap ring having fingers that engage the electrical receptacle and urge it toward the housing of the lighting fixture using a spring force. This is disclosed in U.S. Pat. No. 4,477,143. The electrical receptacle may be lifted up against the spring force and turned to orient the receptacle North. Circumferential holes located in an upper circular end plate of the electrical receptacle receive pins formed around an opening in the housing for securing the electrical receptacle to the housing. In another approach in which no snap ring is used, the electrical receptacle is oriented by loosening a screw in the top of the receptacle, rotating the receptacle until indicia on the receptacle points to the desired position and then re-tightening the screw.

The photoelectric controller is subjected to harsh environments at certain times and at certain locations. For example, the photoelectric controller may be used to control streetlights in arid climates where there are dust storms. It also may be subjected to snow and ice. The window may become coated with dust, snow and ice, interfering with proper operation of the photosensor. Maintenance vehicles will periodically spray the photoelectric controller with high pressure water to clean the window. High pressure water spray, high velocity dust, snow, ice and extended periods of direct sunlight is a problematic environment for a high voltage electronic device to be subjected to.

### BRIEF DESCRIPTION OF THE INVENTION

One embodiment of this disclosure pertains to a photoelectric controller device including a housing. An electrically insulating base plate is secured in the housing. At least two printed circuit boards are secured to the base plate in an interior of the housing (e.g., in electrical contact with each other). The printed circuit boards include a photosensor that enables power to a device (e.g., a lighting fixture) to be controlled in response to ambient light and communication circuitry for sending signals that communicate with the device. Electrically conductive, main terminals are secured in electrical contact with one of the printed circuit boards for providing power to the device as well as to the circuitry on the printed circuit boards. A communication terminal is also secured in electrical contact with the communication circuitry on one of the printed circuit boards. Reference to circuitry herein includes various electrical components used in the circuitry (e.g., capacitors, resistors, photosensor, diodes) as well as conductive paths included in the circuitry between the components.

Referring to specific features of this embodiment, the base plate is secured near an open end of the housing. The housing can comprise a window aligned with the photosensor. The housing can be cup shaped and can include a larger diameter body portion near an open end portion thereof. The larger diameter body portion can include a circumferentially extending shoulder and spaced apart ramp members extending outwardly of the shoulder (i.e., at a slope that decreases toward the open end). The base plate can be snap fit against the ramp members into contact with the shoulder. The base plate can include spaced apart cutouts or recesses on an outer surface thereof that engage the ramp members. Polymeric resin can optionally be used to secure the base plate to the housing.

In another aspect, the housing can include circumferentially spaced openings and the base plate can include circumferentially spaced, interiorly threaded portions at a periphery thereof aligned with the openings. Fasteners extend through the openings into the threaded portions.

The base plate can include an interior surface and fingers extending from the interior surface including ramp members at end portions thereof that enable an outer one of the printed circuit boards to be snap fit against said ramp members into contact with the fingers. The slope of the ramp members of the fingers decreases away from the open end.

The base plate can include first polymeric risers extending from an inner surface thereof through openings in an outer one of the printed circuit boards into contact and bonded with an inner one of the printed circuit boards. A second polymeric riser can extend from the inner surface of said base plate into contact and bonded with the outer circuit board. The main terminals are disposed inside the first risers and are secured in electrical contact with circuitry on the inner printed circuit board and the communication terminal is disposed inside the second riser into electrical contact with the communication circuitry on the outer printed circuit board.

The housing includes a window opening formed in a wall of the housing. The wall can include a channel surrounding the window opening and a window pane comprised of light transmitting material received in the channel.

The main terminals can each be arcuate and L-shaped external to the base plate. The main terminals are (e.g., circumferentially) spaced around the communication or signaling terminal (e.g., a dimming terminal). The communication terminal can be circular or ring shaped, for example, it can comprise a centrally located pin and a surrounding ring member around which the main terminals are disposed (i.e., an RCA contact), a pin only or a ring member only. Also, more than two communication members may be used each having a circular or ring shape, for example, a central pin surrounded by two ring members.

The printed circuit boards can include two printed circuit boards extending in contact with and along a plane of the base plate (e.g., oriented parallel with each other and to the base plate plane) and a third printed circuit board oriented transverse (e.g., substantially perpendicular) to the two printed circuit boards. The third printed circuit board can include circuitry for enabling wireless (e.g., RF) communication between the photoelectric controller device and another device at a remote location. However, it is possible to embed wireless communication circuitry in the second printed circuit board as micro chips gets smaller and more efficient. The third printed circuit board can be flexible. The housing can include a protective coating and the window can include a protective coating comprised of light transmissive material. For example, this coating on at least the window and possibly on the entire photoelectric controller can be a thin film of the transparent compound, indium tin oxide.

Referring to a more specific aspect of the first embodiment, the photoelectric controller device includes a housing including a window opening formed in a wall of the housing. The wall includes a channel surrounding the window opening. A window pane comprised of light transmitting material is received in the channel. An electrically insulating base plate is secured at an open end of the housing. The housing and the base plate include structure enabling the base plate to be snap fit against the housing. At least two printed circuit boards are secured in an interior of the housing and are fastened to the base plate. The printed circuit boards include a photosensor that enables power to a lighting fixture to be controlled in response to ambient light, and dimming circuitry enabling the lighting fixture to be dimmed. Electrically conductive, main terminals are secured in electrical contact with one of the printed circuit boards and extend through the base plate to provide power to the lighting fixture and circuitry on the printed circuit boards. A circular or ring shaped electrically conductive, dimming terminal is secured in electrical contact with the dimming circuitry on one of the printed circuit boards and extends through the base plate.

Referring to more specific features of this aspect of the disclosure, the printed circuit boards include a third printed circuit board oriented transverse to the two printed circuit boards. The third printed circuit board can include circuitry for enabling wireless communication between the photoelectric controller device and another device at a remote location. The third printed circuit board can be flexible. The base plate can include first polymeric risers extending from an inner surface thereof through openings in an outer one of the printed circuit boards into contact and bonded with an inner one of the printed circuit boards. A second polymeric riser extends from the inner surface of the base plate into contact and bonded with the outer circuit board. The main terminals are disposed inside the first risers and are secured in electrical contact with circuitry on the inner printed circuit board and the dimming terminal is disposed inside the second riser into electrical contact with the dimming circuitry on the outer printed circuit board. Any other of the specific features described above with regard to the first embodiment, may be used in any combination with this embodiment.

A second embodiment features a photoelectric controller device including a housing including a window opening formed in a wall of the housing. The wall includes a channel surrounding the window opening. A window pane comprised of light transmitting material is received in the channel. At least one printed circuit board is secured in an interior of the housing. Electrically conductive, main terminals are secured in electrical contact with the printed circuit board.

Referring to features of this second embodiment of this disclosure, the window pane can include a chamfered ridge that is snap fit against the wall. A circular or ring shaped, communication terminal can be secured in electrical contact with one of the printed circuit boards.

A third embodiment features a photoelectric controller device including a cup shaped housing that includes a larger diameter body portion near an open end portion thereof. The larger diameter body portion includes a circumferentially extending shoulder and spaced apart ramp members extending outwardly of the shoulder along a longitudinal axis of the photoelectric controller device (i.e., toward the open end of the housing). A base plate is snap fit against the ramp members into contact with the shoulder. At least one printed circuit board is secured in an interior of the housing to the base plate. Electrically conductive, main terminals are secured in electrical contact with the printed circuit board and extend through the base plate.

Referring to specific features of the third embodiment, the base plate includes spaced cutouts or recesses on an outer surface thereof that engage the ramp members. Polymeric resin can secure the base plate to the housing.

A fourth embodiment features a controller device including a conducting or insulating housing and an electrically insulating base secured in the housing. At least one printed circuit board is secured to the base in an interior of the housing. The printed circuit board includes a sensor selected from the group consisting of a photosensor, infrared sensor, visible detector, and combinations thereof, that enables power to a device (e.g., a lighting fixture) to be controlled in response to ambient light or detection of an object. The printed circuit board also includes communication circuitry that sends signals that communicate with the device. Main electrically conductive terminals are secured in electrical contact with the printed circuit board for providing power to the device. A communication terminal is secured in electrical contact with the communication circuitry on the printed circuit board. The communication terminal can be circular or ring shaped, for example, it can comprise a centrally located pin and a surrounding ring member around which the main terminals are disposed (i.e., an RCA contact), a pin only or a ring member only. Also, more than two communication members may be used each having a circular or ring shape, for example, a central pin surrounded by two ring members.

Referring to specific features that can apply to this fourth embodiment, the controller device can include a second printed circuit board which, for example, is generally parallel or orthogonal to the (first) printed circuit board. The second circuit board can include circuitry for enabling wireless communication between the controller device and another device at a remote location. The circuit board can be generally circular. Any of the other specific features described above regarding the other embodiments can apply to the fourth embodiment.

Many additional features, advantages and a fuller understanding of the invention will be had from the accompanying drawings and the Detailed Description of the Invention that follows. It should be understood that the above Brief Description of the Invention describes the invention in broad terms while the following Detailed Description of the Invention describes the invention more narrowly and presents embodiments that should not be construed as necessary limitations of the broad invention as defined in the claims.

### BRIEF DESCRIPTION OF THE DRAWINGS

FIG. 1 is a perspective view of a photoelectric controller of this disclosure including its upper surface;

FIG. 2 is a perspective view of the photoelectric controller of FIG. 1 including its lower surface;

FIG. 3 is a bottom plan view of the photoelectric controller of FIG. 1;

FIG. 4 is an exploded perspective view of the photoelectric controller of FIG. 1;

FIG. 5 is a cross-sectional diagrammatic view of a lighting fixture to which the photoelectric controller device of FIG. 1 is electrically connected;

FIG. 6 is a perspective view of an inside of the photoelectric controller of FIG. 1 showing an assembly including a base plate and two circuit boards mounted on the base plate as well as a third printed circuit board;

FIG. 7 is an exploded perspective view of the assembly of FIG. 6;

FIG. 8 is a cross-sectional side view of the photoelectric controller of FIG. 1;

FIG. 9 is a perspective cross-sectional view of FIG. 8;

FIG. 10 is a detail view as seen by the dotted lines of FIG. 8;

FIG. 11 is a perspective view showing an alternative way of securing the base plate to the housing of the photoelectric controller; and

FIG. 12 is a block diagram explaining the circuitry of the photoelectric controller device and other devices to which it may communicate.

### DETAILED DESCRIPTION OF THE INVENTION

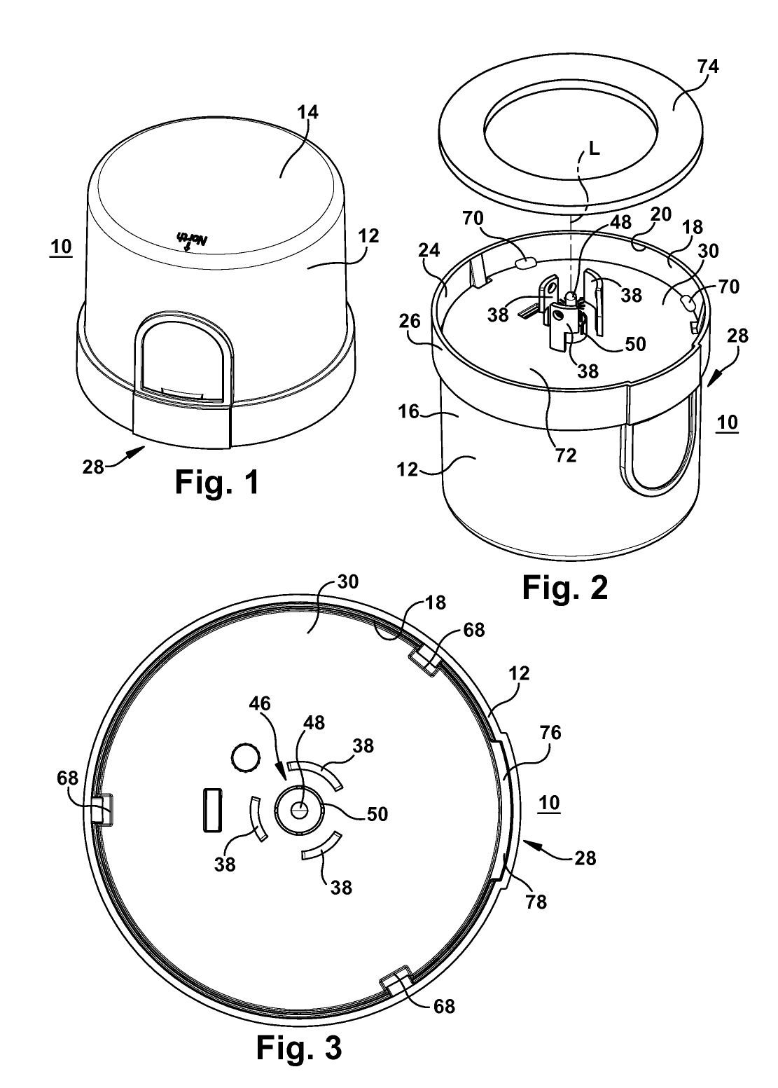

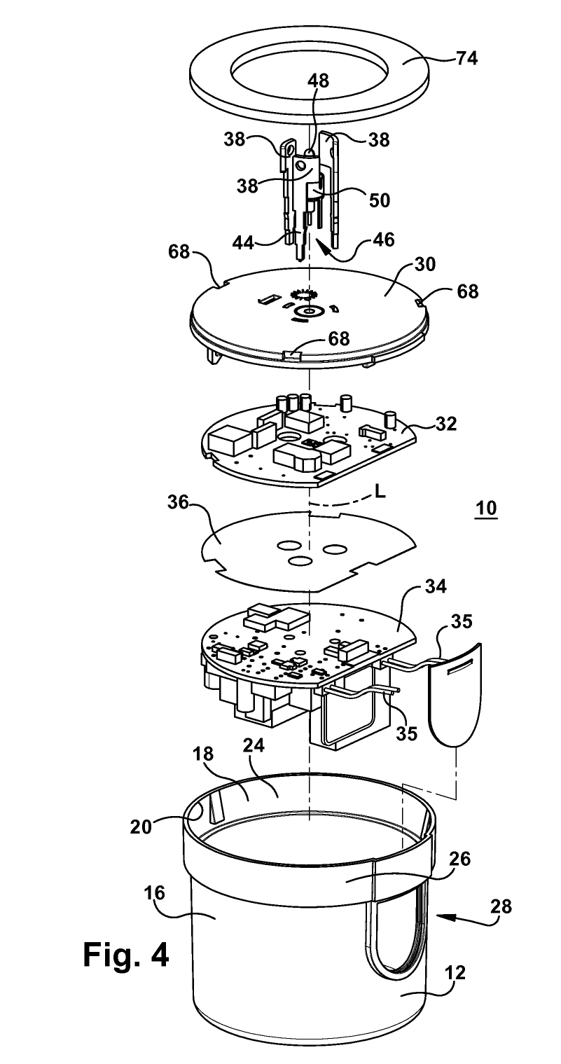

Referring to FIGS. 1-4 of the drawings, a photoelectric controller device 10 includes a housing or cover 12 in the shape, for example, of a generally cylindrical cup. The housing 12 includes an end (e.g., upper) surface 14 and a side wall 16 extending transverse from the end surface to a lip 18 that extends around an open end 20 of the housing 12 leading to its interior 22. The housing 12 is elongated along a longitudinal axis L and includes an interior surface 24 and exterior surface 26. A window 28 is disposed in the side wall 16 of the housing 12. An electrically insulating base plate 30 is secured to the housing near the open end 20. Outer and inner printed circuit boards (PCBs) 32, 34, which are electrically connected to each other such as by the electrical wires 35 between them, are disposed in the interior 22 of the housing 12 and are connected to the base plate 30. An electrically insulating polymer layer 36 is disposed between the PCBs 32, 34. Three main high voltage terminals or contacts 38 extend in a fixed position through the PCBs 32, 34 and the base plate 30, exterior to the base plate 30 and near the open (e.g., lower) end 20 of the housing 12 when it is installed on a lighting fixture 40. The main terminals 38 provide power to the electronic circuitry of the PCBs 32, 34 and to the lighting fixture 40 as described in more detail below. The main terminals 38 are circumferentially positioned and spaced apart from each other in a generally circular orientation. Each main terminal 38 is L-shaped (FIG. 7) and generally arcuate (FIG. 3) near the open end 20 external to the base plate 30 to facilitate electrical contact with connectors of a receptacle 42 during twisting of the photoelectric controller 10. The main terminals 38 each include an elongated portion 44 extending inwardly from the external L-shaped portion. A communication or dimming terminal 46 is circular and/or ring shaped. For example, it includes a central dimming pin 48 and a dimming ring 50 disposed around the dimming pin. The dimming ring 50 and pin 48 are located at a center of the circular orientation of the main terminals 38 (FIG. 3). The dimming pin 48 and dimming ring 50 extend through the outer PCB 32 and the base plate 30 exterior to and at the open end 20 of the photoelectric controller 10. FIG. 1 shows the orientation of the housing 12 as it is secured to the lighting fixture 40 where the open end 20 faces down or directed toward the ground. The PCBs 32, 34 are formed of electrically insulating material such as FR-4, which stands for Flame Retardant Class 4 and is the UL grade designation for glass reinforced epoxy laminate sheets, tubes, rods and printed circuit boards (PCB). FR-4 is made of woven fiberglass cloth with an epoxy resin binder that is flame resistant.

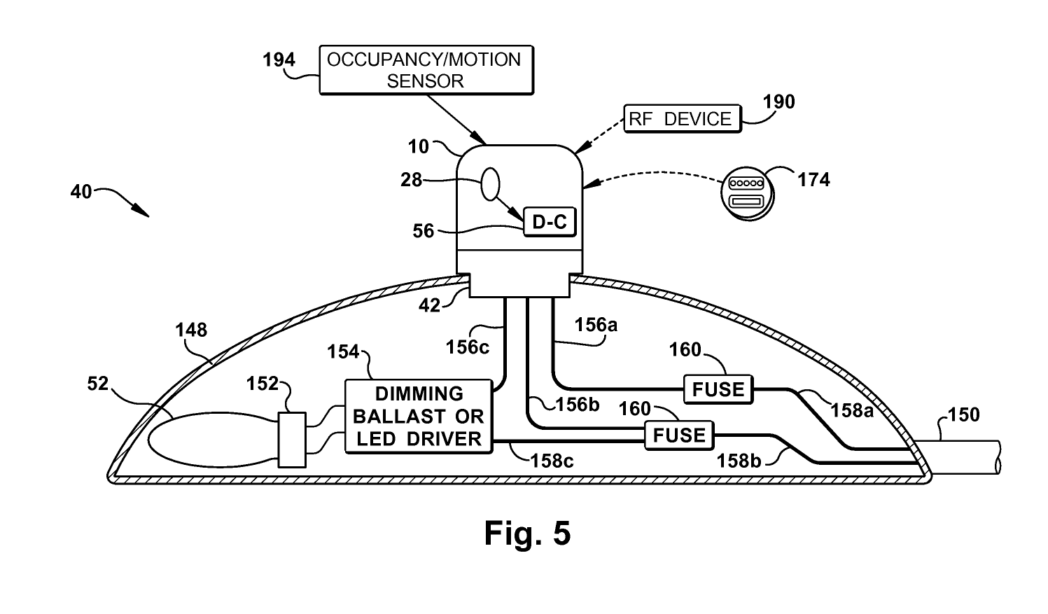

As seen in FIG. 5, the photoelectric controller 10 is inserted and twisted to secure the main terminals 38 into electrical contact with connectors of a receptacle 42 that has been secured to the top of a housing of a lighting fixture 40 such as a streetlight. One example of the receptacle 42 is that disclosed in U.S. patent application Ser. No. 13/101,577, entitled, “Receptacle Connector Between Controller And Lighting Fixture,” which is incorporated herein by reference in its entirety. This insertion and twisting also inserts and maintains the dimming pin 48 and ring 50 into electrical contact with circular or ring shaped connectors of the receptacle, while the photoelectric controller 10 is twisted during its installation atop the lighting fixture 40. The wiring of the lighting fixture 40 that connects to the receptacle 42 and to a lamp 52 and the circuitry of the photoelectric controller 10 will be discussed below.

On one of the PCBs 32, 34 is disposed a photosensor 54 that is aligned with the window 28 so that ambient light is used to control the operation of the lamp 52. In addition, dimming circuitry (a dimming control) 56 is disposed on at least one of the PCBs, enabling the lamp 52 to be dimmed at desired times, ambient lighting conditions or as instructed wirelessly from a remote location. In this regard, a wireless communication device 58 can be disposed on a third PCB 60 that extends perpendicular to the inner PCB 34, which will be discussed in more detail below.

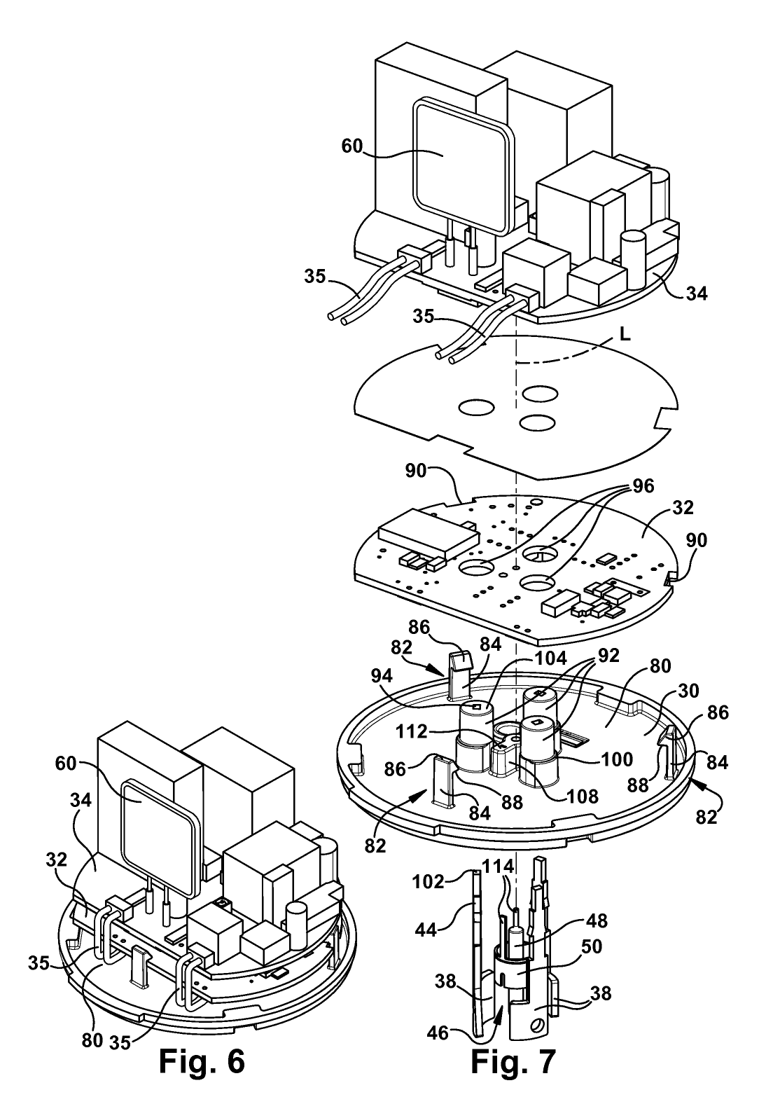

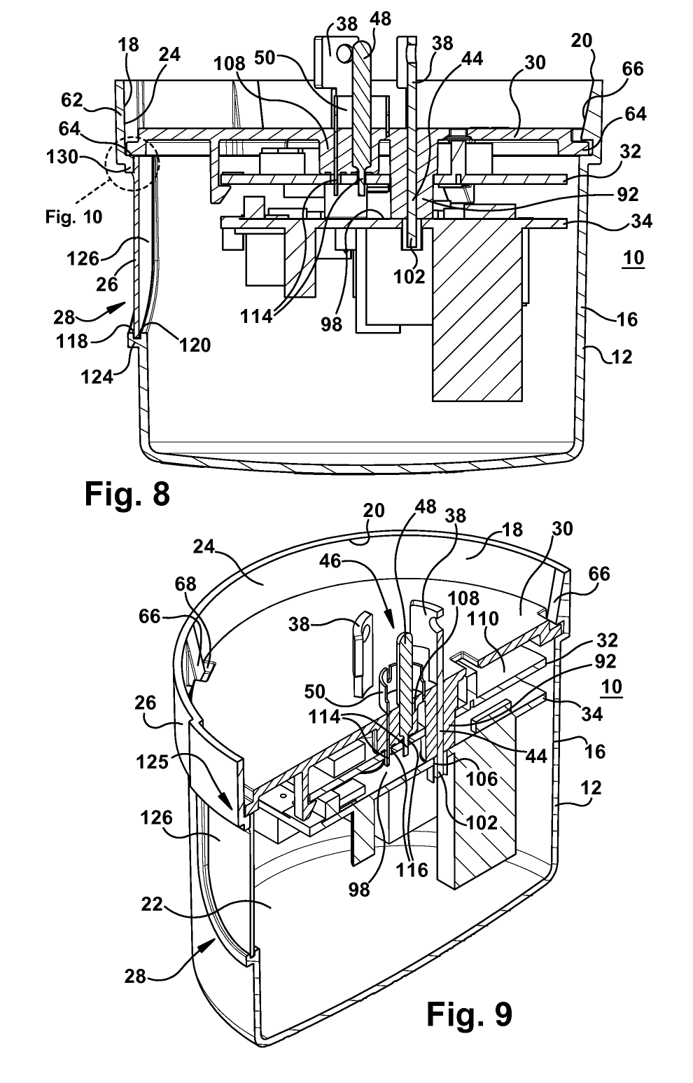

Referring to FIGS. 2, 3 and 8, the housing 12 of the photoelectric controller device 10 includes a larger diameter portion 62 near the open end 20 including a shoulder 64. The interior surface 24 of the housing 12 includes ramped surfaces or tabs 66 located outwardly of the shoulder 64 extending at a declining slope in the longitudinal direction L toward the open end 20. The base plate 30 is generally circular and is snap fit first against the ramped surfaces 66 when moved in the longitudinal direction towards the end surface 14, then into contact with the shoulder 64, which securely fastens the base plate 30 to the housing 12 and prevents movement of the base plate 30 along the longitudinal axis L toward the open end 20. Referring to FIG. 3, the base plate 30 includes cutouts or recesses 68 from a lower surface thereof. Once the base plate 30 has been positioned so that the cutouts 68 are aligned with the ramped surfaces 66, snap fitting the base plate 30 positions the ramped surfaces 66 in each cutout 68, which prevents rotation of the base plate 30 relative to the housing 12. Polymeric resin 70 may also be deposited on outer surface 72 of the base plate 30 against the housing 12, to secure the base plate fixedly to the housing. An O-ring 74 is constructed and positioned to extend into contact with the interior surface 24 of the housing at the lip 18 against the base plate 30, forming a seal between the photoelectric controller device 10 and the receptacle 42 to which it is connected such as using a twist lock feature (FIG. 5). The base plate 30 includes a protrusion 76 that fits into the longitudinal space 78 of the window 28 (FIG. 3). Referring to FIGS. 6 and 7, extending from inner surface 80 of the base plate 30 are spaced apart fingers 82 including a base portion 84 and having ramped surfaces 86 on interior end portions thereof each at a slope that inclines toward the open end 20. This enables the outer PCB 32 to be snap fit against the ramped surfaces 86 into contact with a retaining surface 88 adjacent the ramped surfaces 86, to securely hold the outer PCB 32 in place. The outer PCB 32 includes cutouts or recesses 90 where the fingers 82 are located to prevent rotation of the PCB.

The base plate 30 includes three main risers 92 extending from the inner surface 80 of the base plate. Each of the main risers 92 includes a passage 94 that receives the elongated portion 44 of the main terminals 38 in an interference fit. The main risers 92 pass through openings 96 in the outer PCB 32 and engage outer surface 98 of the inner PCB 34 at shoulders 100 of the main risers where they can be secured with polymer resin. The main risers are secured with polymeric resin to the outer and inner PCBs 32 and 34. An inner end portion 102 of each of the main terminals 38 is exposed from an inner end 104 of the main riser 92 and extends through an opening 106 of the inner PCB 34 where it is soldered in electrical contact with circuitry on the inner PCB. The main riser 92 extends around the main terminal through the opening in the inner PCB 34. (see FIGS. 7-9) The dimming pin 48 and ring 50 can be molded to the base plate 30 in a riser 108 that extends to an outer surface 110 of the outer PCB 32. The inner end 112 of the riser 108 can be secured using resin to the outer PCB 32. Inner end portions 114 of the dimming pin 48 and ring 50 are exposed through the riser 108 and extend through openings 116 in the outer PCB 32 at which point they are soldered into electrical contact with circuitry on the outer PCB. The polymer composition of the base plate 30 is electrically insulating and ensures electrical isolation of the main terminals 38 with each other and with the dimming terminal 46, as well as electrical isolation of the dimming pin 48 from the dimming ring 50.

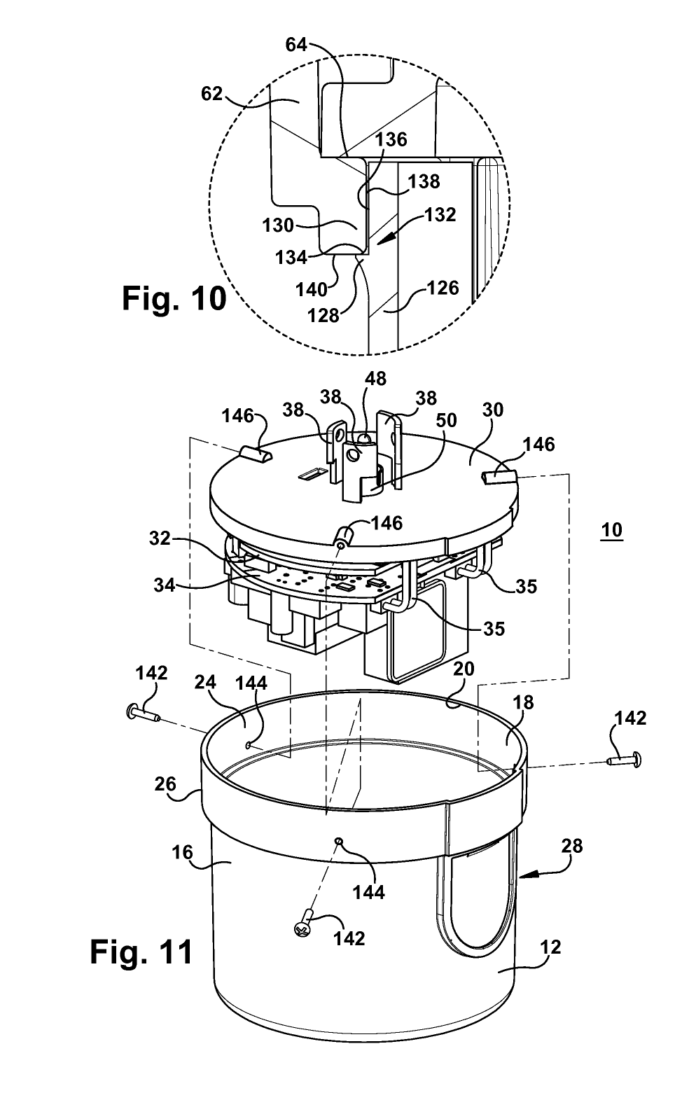

Referring to FIGS. 1, 2, 8 and 10, the window 28 in the housing 12 includes a window opening 118 formed in the side wall 16 of the housing 12. A channel 120 is formed in the side wall 16 around the window opening 118 in an outwardly extending portion 124 of the side wall 16 forming a window frame 125. A window pane 126 is formed of a light transmitting material such a polymer (e.g., polycarbonate) or quartz glass and has a curvature that follows a curvature of the side wall 16 of the housing 12. Referring to FIG. 10, the window pane 126 includes a protruding chamfered ridge 128 formed by an increasing incline from the body of the window pane in a direction along the longitudinal axis L toward a base 130 of the window frame 125. A shoulder 132 is formed near the bottom of the window pane 126 by surfaces 134 and 136. The protruding ridge 128 extends linearly generally parallel to a lower plane of the lip 18 of the housing 12. To install the window pane 126, the window pane is slid into the channel 120 in a direction of the longitudinal axis L toward the end surface 14, until the ridge 128 engages the base 130 of the window frame 125 (FIG. 10) at which point the window pane 126 deflects radially inwardly until it snaps in place once the ridge 128 clears the base frame 130. At this point the window pane 126 has moved radially outwardly so that the ridge 128 engages the base frame 130 and the shoulder 132 rests against the inside surface 138 and ledge surface 140 of the base frame. The window pane 126 can be installed in a water and dust resistant manner without the need for cement. A sealant or a polymer washer could be used around the periphery of the window, which is formed of heat cured epoxy, for example.

Referring to FIG. 11, another way in which the base plate 30 can be secured to the housing 12 is by employing fasteners 142 such as screws. The housing 12 includes circumferentially spaced apart through holes 144 between the interior and exterior surfaces 24, 26 of the housing. Interiorly threaded portions 146 of the base plate 30 are aligned with the through holes 144. The screws 142 are threaded into the threaded portions 146 so that each head is tightened into contact with the exterior surface 26 of the housing 12, pulling the base plate 30 and the interior surface 24 of the housing 12 together, which secures the base plate into a fixed position against the housing.

For outdoor applications it is desired that the housing of the photocontroller is UV and IR stable for prolonged periods of time. Typically, polymeric materials are used for this application. However, a metal housing made of aluminum or aluminum alloy enforced with oxides can be used for the housing. For ease of manufacturing, UV stabilized polymeric materials are used. Polymer degradation is a change in the properties—tensile strength, color, shape, etc.—of a polymer or polymer-based product under the influence of one or more environmental factors such as heat, light or chemicals such as acids, alkalis and some salts. The changes in properties are often termed “aging”. The polymeric material that is being used should retain its structural properties for a prolonged period of time. There are several ways of avoiding UV degradation in plastics—by using stabilizers, absorbers or blockers. For many outdoor applications, the simple addition of carbon black at around a 2% level will provide the protection for the structure by the blocking process. Other pigments such as titanium dioxide can also be effective. Certain strength criteria and materials optical properties should be retained over the lifetime of the device. There are several commercial materials available for the photovoltaic industry by Dupont and SABIC. For example Rynite® (RT Dupont®) Polyester SUV resins were developed specifically for outdoor applications in the photovotaic industry. Zytel® ST801AW BK195 is also an exterior weatherable material—a super-tough 66 nylon used for years in SUV roof racks. SABIC® Xenoy® and Valox® reinforced polycarbonate material also can be used for this purpose. The materials can be further coated with oxide or metal/metal alloys to further improve their weatherability.

Despite the harsh environment to which the photocontroller device is subjected, its design described herein withstands the high pressure water sprayed on it as determined by high pressure water spray tests. The photocontroller passed water tests in which water was projected by a nozzle (6.3 mm) against the device from any direction had no harmful effects. The test duration was three minutes. Water was sprayed at a flow rate of 12.5 liters per minute at a pressure of 30 kN/m² at distance of 3 meters. In addition, the photocontroller passed dust exposure criteria in which ingress of dust need not be entirely prevented, but it must not enter in sufficient quantity to interfere with the satisfactory operation of the equipment. There was complete protection against contact. In addition the photocontroller passed the criteria of being dust tight in which there was no ingress of dust and complete protection against contact. The design of the photoelectric controller enabling it to pass high pressure water spray tests includes the base plate and housing connection and the design of the window.

Features of the lighting fixture and the photoelectric controller device 10 are described in U.S. patent application Ser. No. 12/899,731, entitled “Outdoor Lighting System,” which is incorporated herein by reference in its entirety, portions of which are described below. FIG. 5 shows further details of an exemplary outdoor horizontal lighting fixture 40 with a fixture housing structure 148 having an inlet conduit 150 for receiving power wiring, where the fixture housing 148 may be mounted to a building or to a pole or other support structure for a particular outdoor lighting application. One or more light sources or lamps 52 are supported in the fixture housing 148 via sockets 152, such as incandescent lamps, fluorescent lamps, high intensity discharge (HID) lamps, LEDs or arrays thereof, etc. The light source(s) 52 is driven by a ballast or driver 154, also supported in the housing 148. In certain embodiments the twist-lock receptacle 42 is mounted to the top of the fixture housing 148 for connection of the photoelectric controller device 10. The photoelectric controller device 10 may include the photo sensor 54 operative to sense ambient light near the lighting fixture 40 for controlling turn on and turn off timing or dimming in certain embodiments. The twist-lock connection between the photoelectric controller device 10 and the receptacle 42 provides electrical connection via wires 156a, 156b, and 156c, with two input wires 158a and 158b routed into the housing 148 via the conduit 150, which may optionally be terminated at fuses 160. In one example, a first phase (line) wire 156a connects the power line from the first fuse 160 to a first receptacle terminal and a second phase wire 156b connects the power neutral to the second terminal, with the neutral also being connected from the second fuse 160 to the driver or ballast 154 via wire 158c. The power line is selectively switched by the photoelectric controller device 10 and provided to the ballast or driver 154 via a switched line wire 156c, such that the ballast or driver 154 is selectively powered or unpowered by the operation of the photoelectric controller device 10 which may include a load rated relay contact 162 (FIG. 3) operative according to a switch control signal from the primary microcontroller 164 of the photoelectric controller device 10 to selectively couple the incoming line connection 156a with the switched power line 156c. A dimming control signal may be introduced from a dimming control/command component 56 to within the fixture housing 148 (FIG. 5) through a modification of the twist-lock receptacle 42, such as by including a fourth and/or a fifth conductor (the dimming terminal 46) to convey this signal to the dimming ballast or driver 154 within the housing 148.

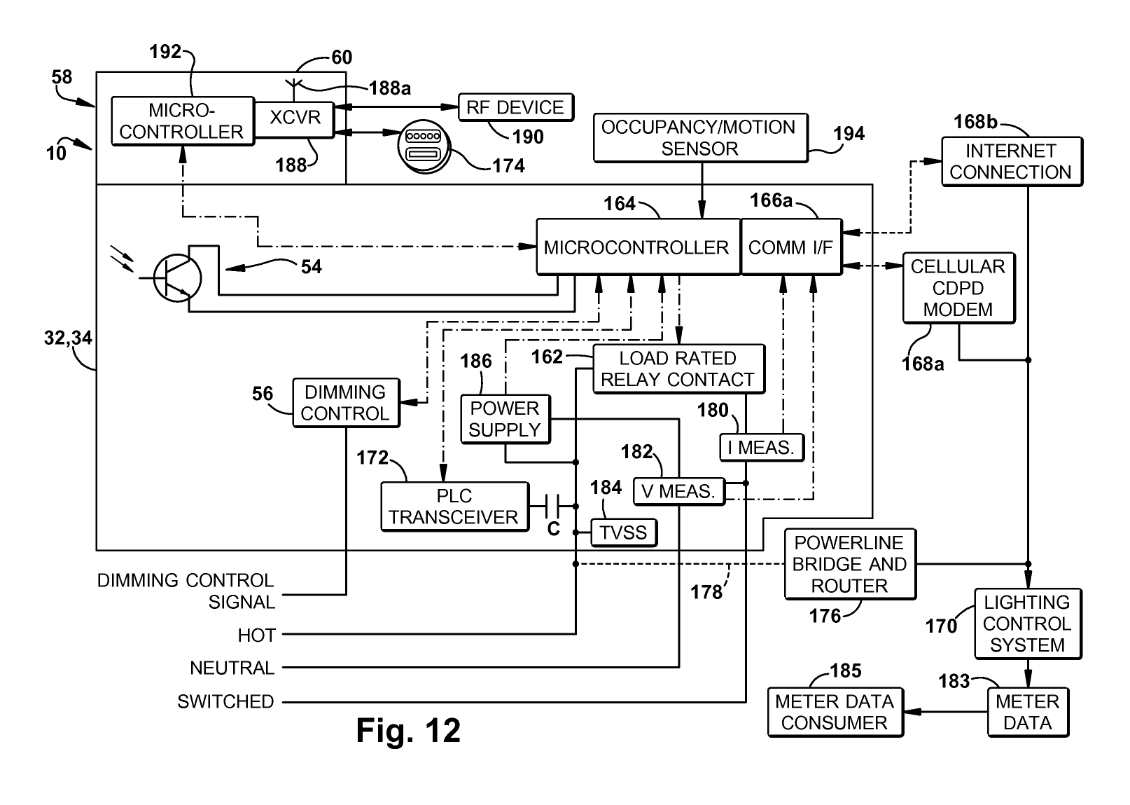

As shown in FIG. 12, the photoelectric controller device 10 includes a dimming component (dimming command or control component) 56, which can be any suitable circuitry, hardware, processor-executed software or firmware, logic, etc., which operates to selectively provide one or more dimming control values or signals to the ballast or driver 154 through the twist-lock receptacle 42 so as to cause the ballast or driver 154 to provide dimmable output from the light source(s) 52. The primary microcontroller 164 includes a communications interface 166a providing communications interfacing with an Internet connection bridging component 168b and/or with a CDPD modem bridging device 168a for ultimate connection with the lighting control system 170. In addition, the photoelectric controller device 10 may include a Power Line Communication (PLC) transceiver 172 and a coupling capacitance C allowing the primary microcontroller 164 to communicate with other fixtures 40, meters 174, and/or a powerline bridge and router 176 via signaling connections 178 on one or both of the line power connections. Moreover, the photoelectric controller device 10 may also include current and/or voltage measurement or sensing circuitry or components 180 and 182 for sensing input or switched power conditions for intelligent (e.g., feedback-type) dimming control. The lighting control system 170 can obtain meter data 183 desired from a meter data consumer 185 from PLC-enabled utility meters 174.

The photoelectric controller device 10 can include transient voltage surge suppression (TVSS) 184 for protecting the photoelectric controller device 10 from voltage surges on an input power line. An example TVSS device 184 for use in the module is a metal oxide varistor (MOV) surge suppressor. The input power line supplies power to a power supply 186 (e.g., at 120-480 volts), which can include a transformer, rectifier and a voltage regulator circuitry. The power supply 186 supplies power, for example DC power, to various components within the photoelectric controller device 10, such as the primary microcontroller 164 and dimming control 56.

The photoelectric controller device 10 can include a wireless communications printed circuit board 60 (which can be positioned perpendicular to the inner and outer PCBs)(FIGS. 7 and 12). The wireless communications printed circuit board 60 (e.g., the third PCB) has a transceiver 188 with an antenna 188a (which can extend on the inner surface of the housing) for RF communications according to one or more protocols with other RF devices 190 (e.g., external RF control devices), other RF-enabled light fixtures, and/or with one or more RF-enabled utility meters 174. In an embodiment, the wireless communications printed circuit board 60 includes a microcontroller 192 for controlling the RF communications of the transceiver 188. The microcontroller 192 on the wireless communications printed circuit board 60 communicates with the primary microcontroller 164, which can allow for wireless remote control of the lighting fixture 40. In an embodiment, the RF communications of the transceiver 188 are directly controlled by the primary microcontroller 164, and the microcontroller 192 on the wireless communications printed circuit board 60 is optional.

The photoelectric controller device 10 in certain embodiments also includes the photo sensor 54 which senses ambient light proximate the lighting fixture 40 and provides a sensed light signal or value to the dimming component 56. Instead of or in addition to the photosensor 54, an infrared sensor or visible detector (e.g., a camera) may be used. The dimming component 56 selectively provides the dimming control value or values (e.g., 0-10V signal, messages, etc.) to the ballast or driver 154 in certain embodiments based at least in part on the sensed light signal or value. For example, the dimming component 56 may be programmed or otherwise configured to provide dimmed light via the dimming control value selection at dawn and/or dusk for reduced power consumption and for aesthetic lighting, rather than the conventional full on/full off operation. In certain embodiments, moreover, the dimming component 56 may be operative to selectively dim the light output during certain times for energy conservation, for instance, to dim unused roadways to a safe but efficient level in the middle of the night, with possible dimming control modification/override according to signals or values received from an occupancy/motion sensor 194 operatively coupled with the primary microcontroller 164. In certain embodiments, moreover, the dimming control component 56 may be implemented as one or more software components executed by the primary microcontroller 164. The dimming control component 56 can include dimming control switches that are settable by a user to program various dimming parameters, such as dimming level for example. Alternatively, such dimming parameters can be set by downloading parameter settings to the photoelectric controller device 10, either locally or remotely.

In certain embodiments, the dimming component 56 is operative to selectively provide the dimming control value based at least in part on a received RF signal or value from an external RF device 190. For instance, an RF command signal can be sent to the photoelectric controller device 10 wirelessly (and such signal can be sent to multiple photoelectric controller devices 10) for initiating dimmed, full on, full off, flashing operation, or combinations thereof by a control device 190 having an RF transmitter, thus allowing security personnel to control outdoor lighting operation. The dimming component 56 may thus provide the dimming control value(s) to control the light output according to one or more criteria, some of which may be externally actuated (e.g., via the photoelectric sensor 54, motion sensor 194, and/or RF device 190 or combinations thereof) and some of which may be preprogrammed in the photoelectric controller device 10.

In addition to the wireless communications printed circuit board 60, the photoelectric controller device 10 can include one or more printed circuit boards 32, 34 (e.g., outer and inner PCBs) containing components and circuitry not provided on the wireless communications PCB. For example, components such as the TVSS 184, power supply 186, load rated relay 162 and photo sensor 54 can be provided on the inner circuit board 34, while the dimming control component 56 and primary microcontroller 164 can be provided on the other outer circuit board 32. Additional circuitry and/or components, or different variations of the circuitry and/or components, can be provided on either circuit board 32, 34. If only one printed circuit board is used, it can include all of the circuitry enclosed by the box 32 or 34 shown in FIG. 12. In addition, the second printed circuit board (oriented generally parallel to or orthogonal to the first board) can includes circuitry for enabling wireless communication between the controller device and another device at a remote location (i.e., the circuitry of wireless communications printed circuit board 60).

The system may also include one or more occupancy/motion sensors 194 operatively coupled with one of the RF-enabled outdoor lighting fixtures 40 or otherwise coupled with the network. For instance, the photoelectric controller device 10 may be operatively coupled with a motion sensor 194 to receive a wired or wireless signal (e.g., via transceiver and antenna 188, 188a) therefrom indicating detected or sensed motion or person/vehicle occupancy near and/or lit by the lighting fixture 40, and the dimming component 56 is operative to selectively provide the dimming control value based at least in part on a sensed motion light signal or value from the motion sensor 194. For example, the dimming component 56 may increase a dimmed power level (or go to full-on operation from a previously dimmed setting) when motion is sensed and continue this modified operation for a predetermined time or until a separate reset command is received at the photoelectric controller device 10. In other embodiments, the dimming control signal can be varied for output light flashing operation based at least in part on a received motion detection signal from the sensor 194.

Many modifications and variations of the invention will be apparent to those of ordinary skill in the art in light of the foregoing disclosure. Therefore, it is to be understood that, within the scope of the appended claims, the invention can be practiced otherwise than has been specifically shown and described.

What is claimed is:

1. A photoelectric controller device comprising:
a housing and an electrically insulating base secured in said housing;
at least two printed circuit boards secured to said base plate in an interior of said housing, said printed circuit boards including a photosensor that enables power to a device to be controlled in response to ambient light and communication circuitry for sending signals that communicate with said device;
main electrically conductive terminals secured in electrical contact with one of said printed circuit boards for providing power to said device; and
a communication terminal secured in electrical contact with said communication circuitry on one of said printed circuit boards.

2. The photoelectric controller device of claim 1 wherein said base plate is secured near an open end of said housing.

3. The photoelectric controller device of claim 1 wherein said housing comprises a window aligned with said photosensor.

4. The photoelectric controller device of claim 2 wherein said housing is cup shaped and includes a larger diameter body portion near an open end thereof, said larger diameter body portion including a circumferentially extending shoulder and spaced apart ramp members extending outwardly of said shoulder toward the open end, and said base plate is snap fit against said ramp members into contact with said shoulder.

5. The photoelectric controller device of claim 4 wherein said base plate includes spaced apart recesses on an outer surface thereof that engage said ramp members.

6. The photoelectric controller device of claim 2 wherein said housing includes circumferentially spaced openings and said base plate includes circumferentially spaced, interiorly threaded portions at a periphery thereof aligned with said openings, and fasteners extending through said openings into said threaded portions.

7. The photoelectric controller device of claim 1 wherein said base plate includes an interior surface and fingers extending from said interior surface including ramp members at end portions thereof that enable an outer one of said printed circuit boards to be snap fit against said ramp members into contact with said fingers.

8. The photoelectric controller device of claim 1 wherein said base plate includes first polymeric risers extending from an inner surface thereof through openings in an outer one of said printed circuit boards into contact and bonded with an inner one of said printed circuit boards, and a second polymeric riser extending from the inner surface of said base plate into contact and bonded with the outer said circuit board, wherein said main terminals are disposed inside said first risers and are secured in electrical contact with circuitry on said inner printed circuit board and said communication terminal is disposed inside said second riser into electrical contact with said communication circuitry on said outer printed circuit board.

9. The photoelectric controller device of claim 1 comprising a window opening formed in a wall of said housing, said wall including a channel surrounding said window opening and a window pane comprised of light transmitting material received in said channel.

10. The photoelectric controller device of claim 1 wherein said main terminals are each arcuate and L-shaped, said main terminals being spaced around said communication terminal.

11. The photoelectric controller device of claim 1 wherein said communication terminal has a circular or a ring shape.

12. The photoelectric controller device of claim 11 wherein said communication terminal comprises a centrally located pin and a surrounding ring member around which said main terminals are disposed.

13. The photoelectric controller device of claim 1 wherein said printed circuit boards include two printed circuit boards in contact with and extending along said base plate and a third printed circuit board oriented transverse to said two printed circuit boards.

14. The photoelectric controller device of claim 13 wherein said third printed circuit board includes circuitry for enabling wireless communication between said photoelectric device and another device at a remote location.

15. The photoelectric controller device of claim 13 wherein said third printed circuit board is flexible.

16. The photoelectric controller device of claim 9 wherein said housing includes a protective coating and said window includes a protective coating comprised of light transmissive material.

17. A photoelectric controller device comprising:
a housing including a window opening formed in a wall of said housing, said wall including a channel surrounding said window opening;
a window pane comprised of light transmitting material received in said channel;
an electrically insulating base plate secured near an open end of said housing, said housing and said base plate including structure enabling said base plate to be snap fit against said housing;
at least two printed circuit boards secured in an interior of said housing and fastened to said base plate, said printed circuit boards including a photosensor that enables power to a lighting fixture to be controlled in response to ambient light and dimming circuitry sending signals enabling said lighting fixture to be dimmed;
electrically conductive main terminals secured in electrical contact with one of said printed circuit boards and extending through said base plate for providing power to said lighting fixture; and
a circular or ring shaped, electrically conductive dimming terminal secured in electrical contact with said dimming circuitry on one of said printed circuit boards and extending through said base plate.

18. The photoelectric controller device of claim 17 wherein said printed circuit boards include a third printed circuit board oriented transverse to said two printed circuit boards.

19. The photoelectric controller device of claim 18 wherein said third printed circuit board includes circuitry for enabling wireless communication between said photoelectric controller device and another device at a remote location.

20. The photoelectric controller device of claim 18 wherein said third printed circuit board is flexible.

21. The photoelectric controller device of claim 17 wherein said base plate includes first polymeric risers extending from an inner surface thereof through openings in an outer one of said printed circuit boards into contact and bonded with an inner one of said printed circuit boards, and a second polymeric riser extending from the inner surface of said base plate into contact and bonded with the outer said circuit board, wherein said main terminals are disposed inside said first risers and are secured in electrical contact with circuitry on said inner printed circuit board and said dimming terminal is disposed inside said second riser into electrical contact with said dimming circuitry on said outer printed circuit board.

22. A photoelectric controller device comprising:
a housing including a window opening formed in a wall of said housing, said wall including a channel surrounding said window opening;
a window including a window pane comprised of light transmitting material received in said channel;
at least one printed circuit board secured in an interior of said housing; and
electrically conductive, main terminals secured in electrical contact with said printed circuit board.

23. The photoelectric controller device of claim 22 wherein said window pane includes a ridge that is snap fit against said wall.

24. The photoelectric controller of claim 22 comprising a circular or ring shaped communication terminal secured in electrical contact with one of said printed circuit boards.

25. A photoelectric controller device comprising:
a cup shaped housing that includes a larger diameter body portion near an open end portion thereof, said larger diameter body portion including a circumferentially extending shoulder and spaced apart ramp members extending outwardly of said shoulder;
a base plate that is snap fit against said ramp members into contact with said shoulder;
at least one printed circuit board secured in an interior of said housing to said base plate;
electrically conductive, main terminals secured in electrical contact with said printed circuit board and extending through said base plate.

26. The photoelectric controller device of claim 25 wherein said base plate includes spaced recesses on an outer surface thereof that engage said ramp members.

27. The photoelectric controller of claim 25 comprising a circular or ring shaped communication terminal secured in electrical contact with one of said printed circuit boards.

28. A controller device comprising:
a conducting or insulating housing and an electrically insulating base secured in said housing;
at least one printed circuit board secured to said base in an interior of said housing, said printed circuit board including a sensor selected from the group consisting of a photosensor, infrared sensor or visible detector, that enables power to a device to be controlled in response to ambient light or detection of an object, and communication circuitry for sending signals that communicate with said device;
main electrically conductive terminals secured in electrical contact with said printed circuit board for providing power to said device; and
a communication terminal secured in electrical contact with said communication circuitry on said printed circuit board.

29. The controller device of claim 28 including a second printed circuit board which is generally parallel or orthogonal to said printed circuit board.

30. The controller device of claim 29 wherein said second printed circuit board includes circuitry for enabling wireless communication between said controller device and another device at a remote location.

31. The controller device of claim 29 wherein said printed circuit board is generally circular.
